(19) United States
(12) Patent Application Publication
(10) Pub. No.: US 2025/0159977 A1
(43) Pub. Date: May 15, 2025

(54) METHOD OF PRODUCING A DEVICE WITH SUPERIMPOSED TRANSISTORS

(71) Applicant: COMMISSARIAT A L'ENERGIE ATOMIQUE ET AUX ENERGIES ALTERNATIVES, Paris (FR)

(72) Inventor: Sylvain BARRAUD, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/799,753

(22) Filed: Aug. 9, 2024

(30) Foreign Application Priority Data
Aug. 11, 2023 (FR) 2308688

(51) Int. Cl. H10D 84/85; H10D 30/00; H10D 30/01; H10D 30/43; H10D 62/10; H10D 62/80; H10D 64/01; H10D 64/23; H10D 84/01

(52) U.S. Cl. CPC H10D 84/851; H10D 30/014; H10D 30/0191; H10D 30/43; H10D 30/502; H10D 62/121; H10D 62/883; H10D 64/017; H10D 64/251; H10D 84/0167; H10D 84/0181; H10D 84/0186; H10D 84/0188

(57) ABSTRACT

A device comprising two transistors stacked along a main direction, the first transistor comprising channels stacked along the main direction and first source and drain contacts, the second transistor comprising channels stacked along the main direction and second source and drain contacts, wherein the first source (respectively drain) contact and the second source (respectively drain) contact are distinct and isolated from one another by a first gate dielectric layer and by a second gate dielectric layer. The invention also relates to a method for manufacturing the device.

### TECHNICAL FIELD

The invention relates to the field of microelectronics technologies. It has a particularly advantageous application in manufacturing advanced CFET (complementary field-effect transistor)-type devices, comprising two gate-all-around N-type and P-type cointegrated transistors.

### PRIOR ART

The evolution of the architecture of transistors, has played a crucial role in the constant improvement of performance of microelectronic devices and their continuous miniaturisation.

Conventional MOSFET (metal-oxide-semiconductor field-effect transistor) based on silicon, has been the cornerstone of the semiconductor industry.

To meet the increasing requirements of integration density, this conventional architecture has then given way to other types of architectures better adapted to performances specified in technological nodes less than 12 nm. The so-called “finFET” architecture makes it possible, for example, to respond to the performances set by 7 nm and 5 nm technological nodes.

More recently, a gate-all-around transistor architecture called GAA transistors and with superposed channels has emerged. This architecture responds to the problems of the next technological nodes, in particular from 3 nm and beyond.

In CFET devices adopting this GAA transistor architecture, two gate-all-around N- and P-type transistors and with distinct stacked channel structures are conventionally juxtaposed.

With the aim of increasing the integration density of microelectronic devices, other GAA architectures of CFET have been developed. Document FR3090998 discloses an architecture based on the superposition of two N- and P-type GAA transistors. This makes it possible to reduce the bulk of the device in an integrated circuit. The method disclosed by this document however remains complex to implement. The number of steps of the method is high. The cost of the method, which depends, in particular, on the number of steps to be implemented, is significant.

A controlled industrial manufacture, satisfying the required quality requirements and limiting the costs of the method, is a significant challenge for developing GAA CFET transistor technologies.

There is therefore a need for a method for manufacturing GAA CFET transistors having a limited manufacturing cost.

An aim of the invention is to respond to this need by proposing such a manufacturing method. Another aim of the invention is to propose a device having a GAA CFET architecture being able to be reproduced more easily and with more control. Another aim of the invention is to overcome at least partially the disadvantages of known methods and devices.

### SUMMARY

To achieve this aim, according to an embodiment, a microelectronic device is provided comprising at least two superposed transistors along a main direction z, comprising:
A first transistor of a first type, comprising:
   at least two first channels stacked along the main direction z, each channel being with the basis of a first semiconductor material,
   a first source and a first drain with the basis of said first semiconductor material,
   a first source contact and a first drain contact connected respectively to said first source and to said first drain,
   a first so-called gate-all-around, totally surrounding at least one of the first channels,
   a first gate dielectric layer separating each first channel from the first gate-all-around,
A second transistor of a second type, comprising:
   at least two second channels stacked along the main direction z, each channel being with the basis of a second semiconductor material,
   a second source and a second drain with the basis of said second semiconductor material,
   a second source contact and a second drain contact connected respectively to said second source and to said second drain,
   a second so-called gate-all-around, totally surrounding at least one of the second channels,
   a second gate dielectric layer separating each second channel of the second gate-all-around.

Advantageously, the first source contact and one from among the second source contact and the second drain contact are distinct and isolated from one another by the first gate dielectric layer and by the second gate dielectric layer.

Advantageously, the first drain contact and the other from among the second source contact and the second drain contact are distinct and isolated from one another by said first gate dielectric layer and by said second gate dielectric layer.

In this architecture, the first and second gate dielectric layers advantageously have at least two functions: the isolation of the first and second channels opposite the first and second gates, and the isolation of the first and second contacts from one another.

This architecture is therefore designed by minimising the number of distinct elements. As each distinct element typically requires at least one manufacturing step, this makes it possible to consider a manufacturing method for this device architecture comprising a limited number of steps.

Another aspect of the invention relates to a method for manufacturing such a microelectronic device, comprising the following steps:
Providing, on a substrate, a first stack and a second stack superposed along the direction z, said first stack comprising a plurality of first layers made of a first material, alternated with a plurality of second layers made of a second material, said second stack comprising a plurality of third layers made of a third material, alternated with a plurality of fourth layers made of a fourth material, said first and second stacks being separated by a dielectric layer,
Forming, in the superposed first stack and second stack, first openings defining first patterns,
Forming a sacrificial gate mounted on the first patterns and partially in the first openings,
Forming, in the first patterns, second openings defining second patterns, on either side of the sacrificial gate,
Forming a first sacrificial layer in the second openings, on flanks of the second layers of the first stack,
Forming a second sacrificial layer on the first sacrificial layer and on flanks of the fourth layers of the second stack, by leaving an access space to the first sacrificial layer,
Removing the first sacrificial layer, from the access space, by preserving the second sacrificial layer, so as to form first cavities opening onto the flanks of the second layers of the first stack,
Removing, from the first cavities, the second material from the second layers selectively at the first material from the first layers, so as to form second spaces,
Forming a first gate dielectric layer in the second spaces on exposed parts of the first material of the first layers, and in the first cavities on exposed parts of the second sacrificial layer,
Depositing a layer with the basis of a first semiconductor material in the second spaces, on the first gate dielectric layer, so as to form:
   the first channels of the first transistor with the basis of the first semiconductor material, in vertical alignment with the sacrificial gate,
   a first source and a first drain of the first transistor with the basis of the first semiconductor material, on either side of the first channels of the first transistor,
Filling the first cavities with a first electrically conductive material to form first source and drain contacts of the first transistor,
Removing the second sacrificial layer, so as to form second cavities opening onto the flanks of the fourth layers of the second stack,
Removing from the second cavities, the fourth material from the fourth layers selectively at the third material from the third layers, so as to form fourth spaces,
Forming a second gate dielectric layer in the fourth spaces on exposed parts of the third material from the third layers, and in the second cavities on the first gate dielectric layer,
Deposing a layer with the basis of a second semiconductor material in the fourth spaces, on the second gate dielectric layer, so as to form:
   second channels of the second transistor with the basis of the second semiconductor material in vertical alignment with the sacrificial gate,
   a second source and a second drain of the second transistor with the basis of the second semiconductor material, on either side of the second channels of the second transistor,
Filling the second cavities with a second electrically conductive material to form source and drain contacts of the second transistor,
Removing the sacrificial gate so as to form third openings,
Removing from the third openings, the first layers and the third layers, to form first spaces and third spaces respectively,
Filling the first and third spaces, to respectively form the first and second gates-all-around of the first and second transistors.

In this method, the first transistor is formed from the first stack and the second transistor is formed from the second stack. A principle of the method according to the invention consists of selectively replacing certain layers of the initial stacks, in this case, the first and third layers, to typically form two superposed gates, surrounding layers with the basis of a semiconductor material forming the channels of the transistors, in this case, the second and fourth layers. The advantages mentioned above for the device apply mutatis mutandis to the method according to the invention. In particular, the number of steps is reduced with respect to known methods.

According to an option, the second and fourth layers are subsequently replaced by one or more semiconductor materials in order to form the channels of the transistors. In this case, the initial stacks do not comprise the semiconductor materials forming the channels of the transistors. The subsequent deposition of the semiconductor materials aims to better preserve the semiconductor materials. According to a preferred option, the semiconductor materials of the first and second channels are with the basis of a two-dimensional (2D) material chosen from among MX2 transition metal dichalcogenides with M taken from among molybdenum (Mo) or tungsten (W), and X taken from among sulphur(S) or selenium (Se). The method makes it possible, in particular, to introduce 2D material layers at the end of the method, after structuration of the stack, and in particular after the formation of the spacers. This advantageously makes it possible to limit the risk of degrading the 2D material during the method. The 2D material is not exposed to all the steps of the manufacturing method. The 2D material is thus preserved.

Such a late introduction of the 2D material during the manufacturing method further makes it possible to use standard microelectronic technologies for the formation and the structuration of the stack. It is not necessary to modify or adapt the standard structuration technological steps to the limitations of using the 2D material. The costs of the method are thus advantageously limited. The method can be more easily implemented in current production lines.

Other aims, features and advantages of the present invention will appear upon examining the description below and the accompanying drawings. It is understood that other advantages can be incorporated.

### BRIEF DESCRIPTION OF THE FIGURES

FIGS. 1A, 2A, 3A, 4, 5, 6, 7, 8, 9, 10, 11, 12, 13, 14, 15, 16, 17, 18, 19, 20, 21, 22, 23 and 24A schematically illustrate along cross-sections xz of the steps of manufacturing a GAA CFET transistor device, common to the first and second embodiments of the present invention.

FIGS. 1B, 2B, 3B, and 24B schematically illustrate along cross-sections yz indicated in the corresponding FIGS. 1A, 2A, 3A, and 24A, the same steps of manufacturing the device as those represented in FIGS. 1A, 2A, 3A, and 24A respectively.

FIGS. 25A, 26A, and 27A schematically illustrate along cross-sections xz, the steps of manufacturing a GAA CFET transistor device which follow the common steps represented in FIGS. 1A, 2A, 3A, 4, . . . , 23 and 24A, according to a first embodiment of the present invention.

FIGS. 25B, 26B, and 27B schematically illustrate along cross-sections yz indicated in the corresponding FIGS. 25A, 26A, and 27A, the same steps of manufacturing the device as those represented in FIGS. 25A, 26A, and 27A respectively, according to a first embodiment of the present invention.

FIGS. 28A, 29A, 30A, 31A, 32A, 33A, and 34A schematically illustrate, along cross-sections xz, the steps of manufacturing a GAA CFET transistor device which follow the common steps represented in FIGS. 1A, 2A, 3A, 4, . . . , 23 and 24A, according to a second embodiment of the present invention.

FIGS. 28B, 29B, 30B, 31B, 32B, 33B, and 34B schematically illustrate, along cross-sections yz, indicated in the corresponding FIGS. 28A, 29A, 30A, 31A, 32A, 33A, and 34A, the same steps of manufacturing the device as those represented in FIGS. 28A, 29A, 30A, 31A, 32A, 33A, and 34A, respectively, according to a second embodiment of the present invention.

In the figures in cross-sections, cutting planes are indicated (A-A′, B-B′, . . . , M-M′) with crossed references to the cutting planes of the corresponding figures. The drawings are given as examples and are not limiting of the invention. They constitute principle schematic representations intended to facilitate the understanding of the invention and are not necessarily to the scale of practical applications. In particular, in the principle diagrams, the thicknesses and/or the dimensions of the different layers, patterns and raised elements are not representative of reality. For reasons of clarity, all of the alphanumeric references are not systematically repeated from one figure to another. It is understood that the elements already described and referenced, when they are reproduced in another figures, typically have the same alphanumeric references, even if these are not explicitly mentioned. A person skilled in the art will identify, without difficulty, one same element reproduced in different figures.

### DETAILED DESCRIPTION

Before starting a detailed review of embodiments of the invention, optional features are stated below, which can optionally be used in association or alternatively:

According to a first embodiment, the first source contact and the second source contact are distinct and isolated from one another by the first gate dielectric layer and by the second gate dielectric layer, and the first drain contact and the second drain contact are distinct and isolated from one another by said first gate dielectric layer and by said second gate dielectric layer.

According to a second embodiment, the first source contact and the second drain contact are distinct and isolated from one another by the first gate dielectric layer and by the second gate dielectric layer, and the first drain contact and the second source contact are distinct and isolated from one another by said first gate dielectric layer and by said second gate dielectric layer.

According to an example, the first gate dielectric layer and the second gate dielectric layer are with the basis of the same material, thus forming a continuous dielectric layer between the first and second source contacts and between the first and second drain contacts.

According to an example, the first semiconductor material has a first type of conductivity, for example N-type, and the second semiconductor material has a second type of conductivity different from the first type of conductivity, for example, P-type.

According to an example, the first semiconductor material and/or the second semiconductor material are with the basis of a two-dimensional (2D) material chosen from among MX2 transition metal dichalcogenides with M taken from among molybdenum (Mo) or tungsten (W), and X taken from among sulphur(S), selenium (Se) or tellurium (Te).

According to another example, the first semiconductor material and/or the second semiconductor material are with the basis of a semiconductor oxide, for example, IGZO (indium gallium zinc oxide)-, In2O3-, IWO (tungsten-doped indium oxide)-, ITO (indium tin oxide)-, IAZO (indium aluminium zinc oxide)-, InGaZnO-, InGaO-, InZnO-based or an amorphous semiconductor oxide.

According to another example, the first semiconductor material and/or the second semiconductor material are graphene-, hexagonal boron nitride “h-BN”-, phosphorene-based.

According to an example, the first and second gates-all-around form one same gate common to the first and second transistors.

According to an alternative example, the first and second gates-all-around are distinct.

According to an example, the first gate totally surrounds each first channel of the first transistor, and the second gate totally surrounds each second channel of the second transistor.

According to an example, the method further comprises the following optional steps:
Forming first spacers between the first gate-all-around and the first source and drain contacts,
Forming second spacers between the second gate-all-around and the second source and drain contacts.

According to an example, the formation of the first and second spacers comprises the following steps:
Preferably forming spacers bordering the sacrificial gate and bearing on the first patterns,
Before the formation of the first sacrificial layer, partially removing, from the second openings, the first material of the first layers selectively at the second material from the second layers, so as to form first spacer cavities, preferably in vertical alignment with the spacers,
Filling the first spacer cavities with a first dielectric material to form the first spacers,
Before the formation of the second sacrificial layer, partially removing, from the second openings, the third material from the third layers selectively at the fourth material from the fourth layers, so as to form second spacer cavities, preferably in vertical alignment with the spacers,
Filling the second spacer cavities with a second dielectric material to form the second spacers.

The first and second spacers are typically called internal spacers.

According to an example, the first and second dielectric materials are identical.

According to an example, the first material of the first layers is identical to the third material of the third layers.

According to an example, the first and second spacers are formed simultaneously.

According to an example, the sacrificial gate comprises a first part and a second distinct part.

According to an example, the removal of the sacrificial gate comprises:
a first removal of the first sacrificial gate part, configured to form a third opening only opening onto flanks of the first layers, of a first side only of the first pattern, followed by a removal of the first layers from said third opening to form the first spaces, and a filling of said first spaces to form the first gate-all-around of the first transistor, and
a second removal of the second sacrificial gate part, configured to form a third opening only opening onto flanks of the third layers, of a second side only of the first pattern, followed by a removal of the third layers from said third opening to form the third spaces, and a filling of said third spaces to form the second gate-all-around of the second transistor.

According to an example, the second gate-all-around is formed before the first gate-all-around.

According to an example, the first removal comprises a formation of an isolation portion on flanks of the second stack at the first side of the first pattern, before filling the first spaces to form the first gate-all-around.

According to an example, the second removal comprises a formation of a second isolation portion on flanks of the first stack at the second side of the first pattern, before filling the third spaces to form the second gate-all-around.

According to an example, the method comprises, before the removal of the sacrificial gate, a separation of the sacrificial gate into a distinct first part and a second part, said first and second sacrificial gate parts extending respectively over the first and second sides of the first pattern, the first removal being done on the first gate part and the second removal being done on the second gate part.

According to an example, before formation of the sacrificial gate, a hard mask is formed on the first patterns, and the separation of the sacrificial gate is done by chemical-mechanical polishing stopping on said hard mask.

The invention generally relates to a GAA transistor microelectronic device and a manufacturing method. Such a microelectronic device can have a “GAA stacked nanosheet”-type architecture, i.e. with stacked nanosheets and totally gate-all-around. A stacked nanowire and totally gate-all-around architecture is also possible.

The nanowires or nanosheets typically each comprise a conduction channel of a transistor. These channels are stacked along a direction z. This means that they each occupy a given level of altitude along the direction z. A level can be defined between two planes perpendicular to the direction z.

Advantageously, the method according to the invention can be implemented to produce MOS GAA transistors for 5 nm and sub-5 nm technological nodes.

A microelectronic device comprising GAA transistors with superposed channels can be advantageously integrated in logic systems having 3D architectures. These transistors can, in particular, be associated with other structural or functional elements, so as to design complex systems.

A particular aspect of the invention relates to the implementation of 2D materials to produce nanowires or nanosheets of the device. These 2D materials have semiconductor properties, in particular by the presence of an electronic gap.

2D materials typically correspond to compounds having a lamellar structure constituted of two-dimensional sheets, stacked along the crystallographic axis c. The atomic bonds within each sheet are strong, of covalent nature. The bonds between sheets are a lot weaker, of the Van der Waals type. These two-dimensional sheets are also called monolayers.

In the scope of the present invention, the monolayers are preferably MX2-type semiconductive monolayers, where M is molybdenum (Mo) or tungsten (W) and X, sulphur(S) or selenium (Se). Each “monolayer” is, in this case, composed of a metal cation plane M inserted between two anion planes X. A monolayer therefore comprises, in this case, typically three atomic planes: the atoms of the transition metal (Mo or W) form a plane sandwiched between two chalcogen planes (S, Se or Te, for example). Each transition metal atom is connected to six chalcogen atoms. These anions are in prismatic trigonal coordination with respect to the metal atoms. The MX2 transition metal dichalcogenide monolayers have a hexagonal atomic array.

The MX2 transition metal dichalcogenide monolayers are preferably MoS2, MoSe2, MoTe2, WS2, WSe2 molybdenum disulphide-based.

An alternative option relates to the implementation of semiconductor oxides to produce the nanowires or nanosheets of the device, for example, IWO, IGZO, ITO, InGaZnO, InGaO, InZnO, In2O3, IAZO. Another option relates to the implementation of graphene, hexagonal boron nitride “h-BN”, phosphorene (also called “Black Phosphorous” BP), in particular in the form of a monolayer.

It is specified that, in the scope of the present invention, the terms “on”, “surmounts”, “covers”, “underlying”, “opposite” and their equivalents do not necessarily mean “in contact with”. Thus, for example, the deposition or application of a first layer on a second layer, does not compulsorily mean that the two layers are directly in contact with one another, but means that the first layer covers at least partially the second layer by being either directly in contact with it, or by being separated from it by at least one other layer or at least one other element.

By a substrate, a film, a layer “with the basis” of a material A, means a substrate, a film, a layer comprising this material A only or this material A, and optionally other materials, for example, doping elements or alloy elements. Thus, a silicon nitride SiN-based spacer can, for example, comprise non-stoichiometric silicon nitride (SiN), or stoichiometric silicon nitride (Si3N4), or also a silicon oxynitride (SiON).

The word “dielectric” qualifies a material of which the electric conductivity is sufficiently low in the given application to serve as an isolator. In the present invention, a dielectric material preferably has a dielectric constant less than 20.

Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” means the carrying out of a part of the method, and can designate a set of substeps.

Moreover, the term “step” does not compulsorily mean that the actions carried out during a step are simultaneous or immediately successive. Certain actions of a first step can in particular be followed by actions linked to a different step, and other actions of the first step can then be resumed. Thus, the term “step” does not necessarily mean single and inseparable actions over time and in the sequence of the phases of the method. By “selective etching with respect to” or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. It is referenced SAB. A selectivity S_{A:B} of 10:1 means that the etching speed of the material A is 10 times greater than the etching speed of the material B.

The different patterns formed during the manufacturing steps typically have a structure intended to evolve during the steps of the method. Thus, the patterns can comprise sacrificial layers of the initial stacks, the 2D material- or semiconductor oxide-based layers, the dielectric layers, continuous or discontinuous. The different patterns aim to form, at the end of the method, “transistor patterns”, each comprising at least one conduction channel, a source and a drain on either side of the channel and a gate surrounding said channel, a dielectric barrier separating the gate of the channel and the drain, respectively the source contacts, from one another. The congregation of the first, second, third and fourth layers in the initial stacks can be inverted or swapped.

A preferably orthonormal system, comprising the axes x, y, z is represented in the accompanying figures.

In the present patent application, thickness will preferably be referred to for a layer or a film, and height will be referred to for a device or a structure. The thickness is taken along a direction normal to the main extension plane of the layer or of the film. Thus, a superficial silicon layer (topSi) typically has a thickness along z. A gate pattern formed on such a superficial layer has a height along z. The relative terms “on”, “surmounts”, “under”, “underlying” refer to positions taken along the direction z. A “lateral” dimension corresponds to a dimension along a direction of the plane xy. By a “lateral” extension or “laterally”, this means an extension along one or more directions of the plane xy. The flanks extend, in this case, typically along a plane yz.

An element located “in vertical alignment with” or “to the right of” another element means that these two elements are both located on one same line perpendicular to a plane in which a lower or upper face of a substrate mainly extends, i.e. on one same line oriented vertically in the figures in cross-section.

The terms “substantially”, “about”, “around” mean plus or minus 10%, and preferably plus or minus 5%. Moreover, the terms “between . . . and . . . ” and equivalents mean that the limits are inclusive, unless mentioned otherwise.

The description below has examples of implementations of the method according to the invention in a context of developing a complex 3D device. The scope of this description is clearly not limiting of the invention.

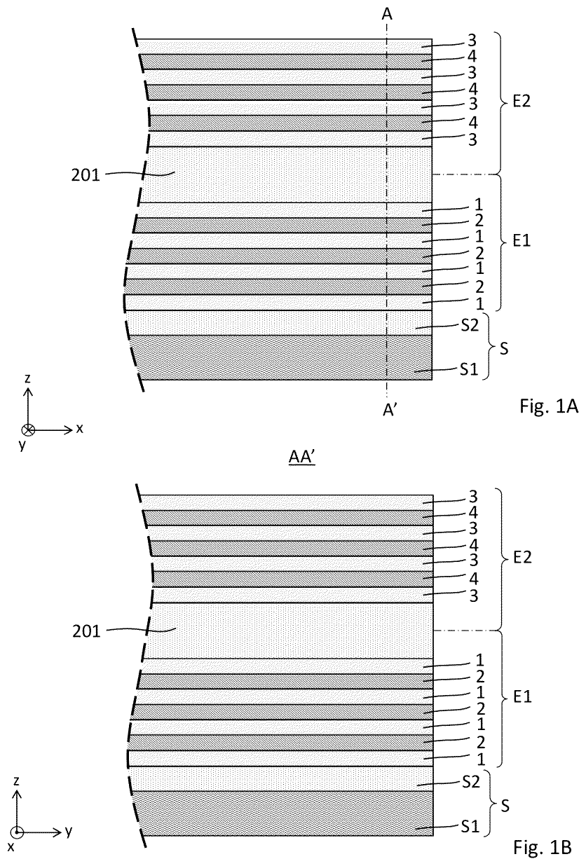

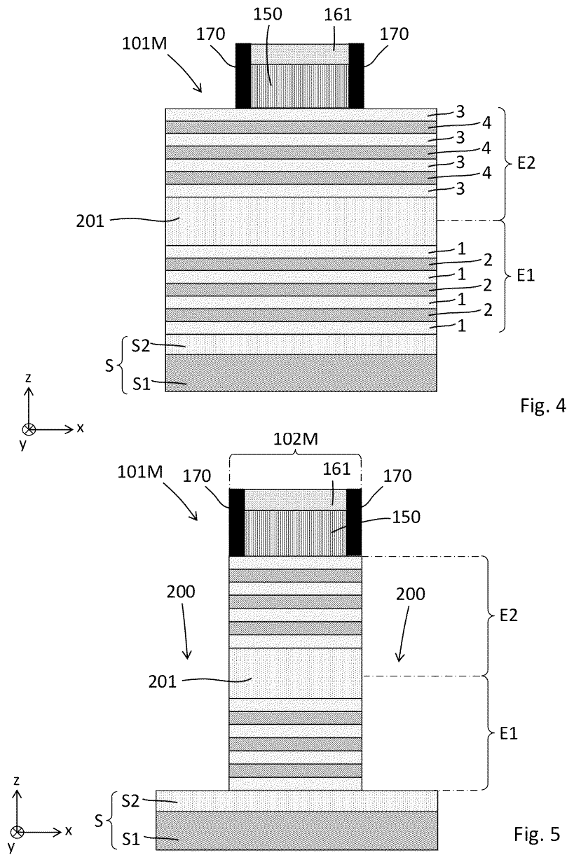

FIGS. 1A, 1B, 2A, 2B, 3A, 3B, 4 to 23, 24A, 24B, 25A, 25B, 26A, 26B, 27A, 27B schematically illustrate steps of manufacturing a CFET device with superposed GAA transistors having source and drain contacts isolated by at least one gate dielectric layer, according to a first embodiment of the present invention. Figures nA (n=1, 2, 3, 24, 25, 26, 27) and FIGS. 4 to 23 correspond to first cross-sections along a plane xz, each illustrating a different step of the manufacturing method. Figures nB (n=1, 2, 3, 24, 25, 26, 27) correspond to second cross-sections along a plane yz, each illustrating the same step as the corresponding figure nA.

As illustrated in FIGS. 1A, 1B, a first step consists of producing, on a substrate S, a superposition along the direction z of a first stack E1 comprising an alternance of semiconductive layers 1, 2 and of a second stack E2 comprising an alternance of semiconductive layers 3, 4, the stacks E1, E2 being separated by an isolating layer 201.

The substrate S can be an SOI (Silicon On Insulator)-, GeOI (Germanium On Insulator)-, or SGOI (Silicon-Germanium On Insulator)-type substrate. These known substrates comprise, according to the current terminology for a person skilled in the art, a so-called “Si bulk” thick silicon layer S1, a so-called “BOX” (Buried Oxide) silicon oxide layer S2 and a thin superficial layer, respectively silicon-, germanium- or silicon-germanium-based. This thin superficial layer can advantageously correspond to the first layer 1 of the first stack E1. Alternatively, the substrate S can be an “Si bulk” solid substrate.

The first stack E1 comprises, according to an example, an alternance of first silicon-germanium (SiGe) layers 1 and second silicon (Si) layers 2. Advantageously, the second stack E2 also comprises an alternance of third silicon-germanium (SiGe) layers 3 and fourth silicon (Si) layers 4. Generally, the pair of materials forming the third layers 3 and the fourth layers 4 of the second stack E2 can be different from the pair of materials forming the first layers 1 and the second layers 2 of the first stack E1. Below, the same pair of materials forming the layers 1, 2 and the layers 3, 4 is adopted.

The concentration of Ge in the SiGe alloy can be 20%, 30% or 45%, for example. This concentration of germanium is chosen, so as to enable a good selectivity of the etching of SiGe with respect to Si, during the selective etching steps. The greater the concentration of Ge will be, the greater the Si selectivity will be during the subsequent removal of SiGe.

The first stack E1 is typically formed on a first substrate and the second stack E2 is typically formed separately on a second substrate. The alternance of the layers 1, 2 and 3, 4 in the respective stacks E1, E2 is advantageously formed by epitaxy of the SiGe 1, 3 and Si 2, 4 layers. This step of forming each stack E1, E2 is inexpensive and well-known to a person skilled in the art. The thicknesses of the Si and SiGe layers can typically be around 10 nm, and more generally, between 5 nm and 20 nm, for example. In a known manner, in order to avoid the formation of structural defects, the maximum thicknesses permitted for the SiGe layers 1, 3 depend, in particular, on the concentration of Ge chosen.

An oxide deposition, for example SiO2-based, is preferably done on each stack E1, E2. The assembly and the superposition of the two stacks E1, E2 can thus be done in a known manner by oxide/oxide transfer and bonding. After bonding, the first stack E1 is thus separated from the second stack E2 by a continuous isolating layer 201, the thickness of which can be typically between 10 nm and 100 nm.

In the example illustrated in FIGS. 1A, 1B, four SiGe layers 1, 3 are respectively alternated with three epitaxially grown Si layers 2, 4. A super Si/SiGe array is thus obtained. The number of Si and SiGe layers can naturally be increased. This ultimately makes it possible to increase the number of channels stacked per transistor in the final device.

Generally, the material(s) forming the layers 1, 3 and the material(s) forming the layers 2, 4 are chosen, such that they can be etched selectively with one another, in particular that of the layers 1 with respect to that of the layers 2 or vice versa, and that of the layers 3 with respect to that of the layers 4 or vice versa. Thus, other pairs of materials are possible. By respecting this condition of selectivity at the etching, the materials forming the layers 1, 2, 3, 4 can be chosen from among the dielectric materials (oxides and nitrides, for example), semiconductor materials, metallic materials.

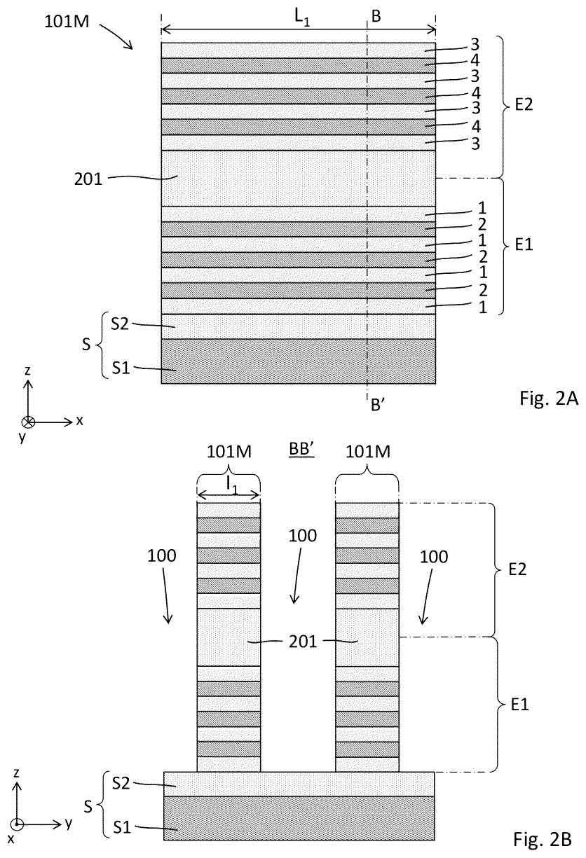

As illustrated in FIGS. 2A, 2B, a conventional lithography/etching step is carried out in order to define first patterns 101M, and first openings 100. The etching is anisotropic and directed along z. It is configured to etch all of the stacks E1, E2, in this case, the two super Si/SiGe arrays separated by the isolating layer 201, over its entire height, by stopping on the substrate S, in this case, the BOX S2. It can be done by plasma by using an HBr/O2 etching chemistry. The first patterns 101M can have a length L1 along x of between 10 nm and 500 nm. They preferably have a width I along y of between 10 nm and 120 nm, for example, around 40 nm. This first structuration of the stacks E1, E2 in the form of fins, makes it possible to define a plurality of superposed nanowires or nanosheets.

For clarity, the following figures iB (i=3, 24, . . . , 34) only illustrate one single “fin” pattern 101M.

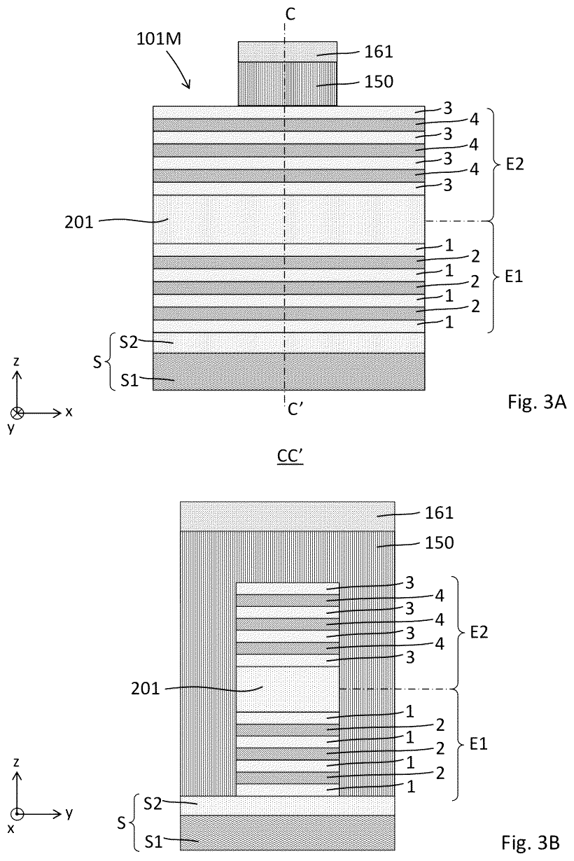

As illustrated in FIGS. 3A, 3B, sacrificial gates 150 are then formed on the “fin” patterns 101M. The formation of these sacrificial gates 150 is done typically by deposition, then lithography/etching. The formation of the sacrificial gates 150 is configured, such that the sacrificial gates 150 are mounted on the “fin” patterns 101M, as illustrated in FIG. 3B. The sacrificial gates 150 typically comprise an upper part located on the “fin” pattern 101M, and lateral parts located on the lateral flanks of the “fin” pattern 101M. The sacrificial gates 150 typically bear on the substrate S. At this stage, the sacrificial gates 150 are typically surmounted by an etching mask 161, called hard mask, implemented in the structuration of the sacrificial gates 150. The sacrificial gates 150 comprise, for example, in a known manner, a thin SiO2 oxide layer (thickness between 3 nm and 7 nm, for example) and a thick polycrystalline silicon or amorphous silicon layer. The thin SiO2 oxide layer (not illustrated in the figures) can form a stop layer during the etching of the polycrystalline silicon of the sacrificial gates 150. This thin SiO2 oxide layer is thus inserted between the sacrificial gates 150 and the “fin” patterns 101M. The hard mask 161 can be silicon oxide SiO2-, silicon nitride SiN-based, or an SiO2/SiN bilayer.

As illustrated in FIG. 4, spacers 170 are then formed on the flanks oriented along yz of the sacrificial gates 150. Generally, projecting along z, these spacers form a continuous ring around each sacrificial gate 150, with a closed contour. However, in a cross-section, along the plane xz illustrated in FIG. 4, the spacer 170 has two parts opposite one another on each of the flanks of the sacrificial gate 150. These two parts are generally designated as being the spacers 170, even if these can be considered as belonging to one single and same spacer. The spacers 170 typically extend up to an upper face of the hard mask 161. The spacers 170 are typically silicon nitride SiN-based, or on the basis of a dielectric material with low dielectric constant, for example, SiCO-based.

As illustrated in FIG. 5, after formation of the spacers 170 by deposition/etching, the anisotropic etching along z is extended in order to define second patterns 102M, and second openings 200. The etching is configured to etch all of the stacks E1, E2 over its entire height, by stopping on the substrate S. It can be done by plasma by using an HBr/O2 etching chemistry.

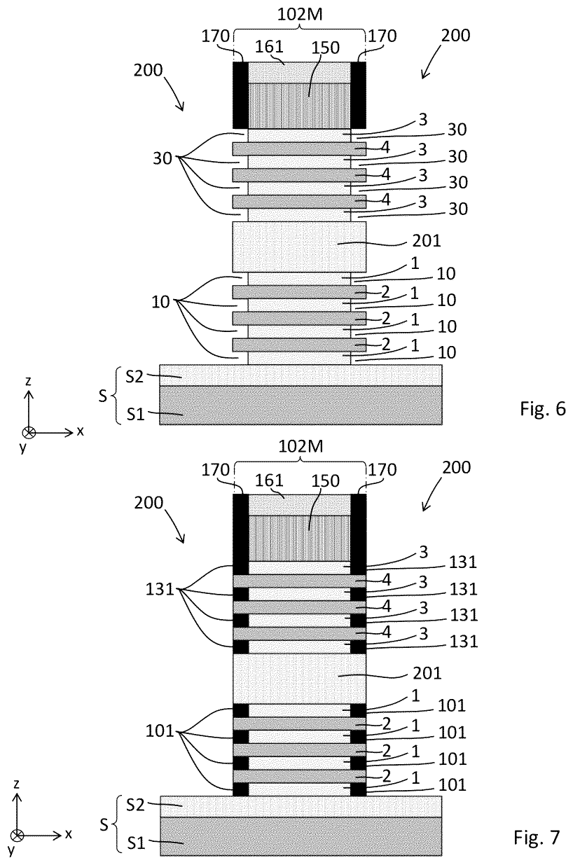

As illustrated in FIG. 6, after formation of the second openings 200, the first layers 1 and the third layers 3 are partially etched selectively at the second layers 2 and at the fourth layers 4 respectively, at the isolating layer 201, at the substrate S and at the spacers 170. The first layers 1 and the third layers 3 are advantageously etched by one same etching. The etching of the material of the layers 1, 3 typically has a selectivity S_{1:2} (S_{3:4}) with respect to the material of the layers 2, 4, of at least 5:1, preferably at least 10:1. This partial etching aims to form first and third spaces 10, 30 in vertical alignment with the spacers 170 respectively in the first and third layers 1, 3. This partial etching is typically stopped at the time. It has an isotropic character and can be done wet or dry, from the second openings 200. From this partial etching, central parts of the layers 1, 3 are preserved under the sacrificial gates 150.

As illustrated in FIG. 7, the first and third spaces 10, 30 are then filled with a dielectric material, for example, with silicon nitride or by a dielectric with low permittivity, to form first and third internal spacers 101, 131. These “internal” spacers 101, 131 are integrated in the stacks E1, E2, preferably in vertical alignment with the spacers 170. They are in contact with the central parts of the layers 1, 3. The formation of the internal spacers 101, 131 is done typically from the second openings 200.

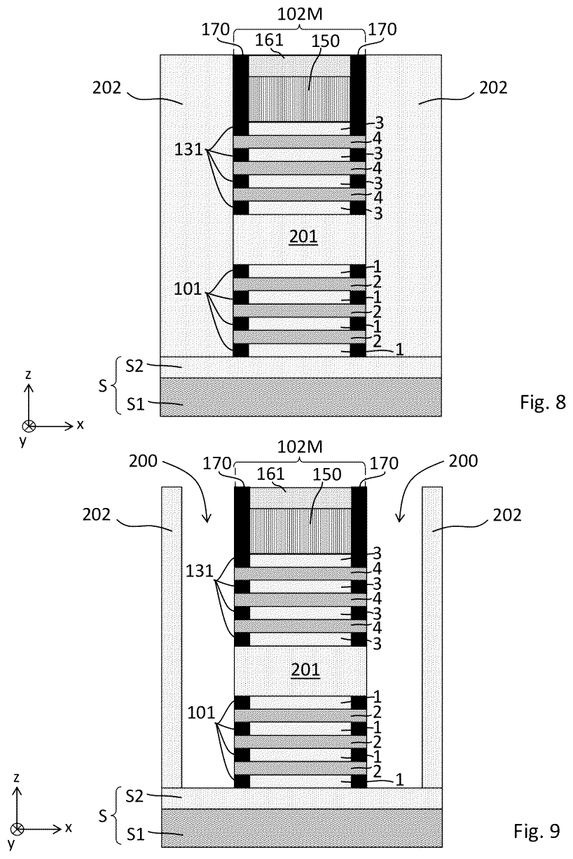

As illustrated in FIG. 8, a dielectric layer 202, for example, SiO2-based, is deposited on and between the second patterns 102M, so as to fill the openings 200. This dielectric layer 202 is then planarised, typically by chemical-mechanical polishing CMP stopping on the hard mask 161.

As illustrated in FIG. 9, the dielectric layer 202 is open by etching, so as to partially reform the second openings 200. The second openings 200 define, in this case, the placement of the contacts of the two stacked transistors.

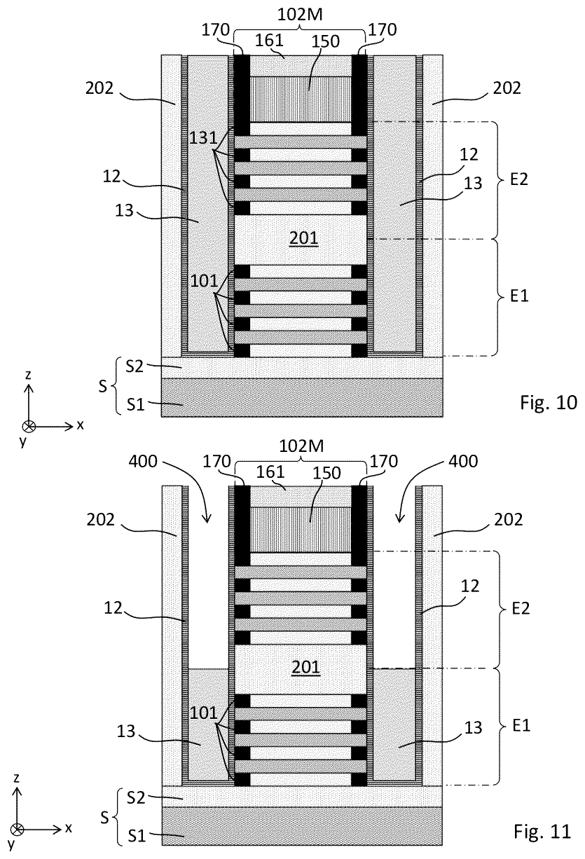

As illustrated in FIG. 10, a conform oxide layer 12 is preferably first deposited in the openings 200. The oxide layer 12 covers the flanks and the bottom of the second openings 200. A first sacrificial layer 13 is then deposited in the second openings 200 on the oxide layer 12, so as to fill the second openings 200. This first sacrificial layer 13 is typically polycrystalline silicon- or amorphous silicon-based. The oxide layer 12 and the sacrificial layer 13 are then typically planarised by chemical-mechanical polishing CMP stopping on the hard mask 161.

As illustrated in FIG. 11, the first sacrificial layer 13 is then partially removed by wet etching, so as to form an access space 400 located opposite the layers 3, 4 of the second stack. The etching is configured such that the remaining part of the first sacrificial layer 13 extends along z up to the isolating layer 201. This wet etching can be with the basis of a TMAH (tetramethylammonium hydroxide) or TEAH (tetraethylammonium hydroxide) ammoniac salt solution.

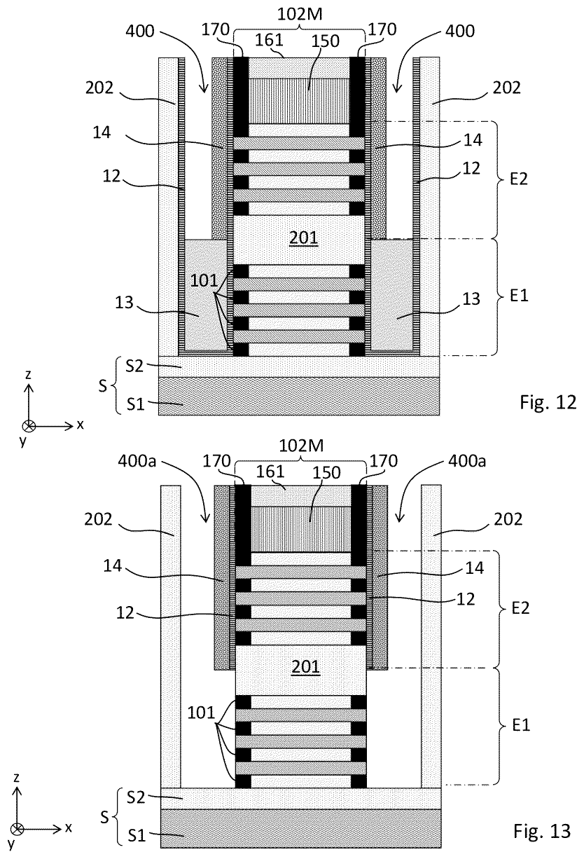

As illustrated in FIG. 12, a second sacrificial layer 14, for example, SiO2-based, is formed in the access space 400, against the pattern 102M and on the remaining part of the first sacrificial layer 13. The formation of this second sacrificial layer 14 is done typically by deposition, then etching. The second sacrificial layer 14 typically extends along z from the isolating layer 201 up to the upper face of the hard mask 161.

As illustrated in FIG. 13, the remaining part of the first sacrificial layer 13 is then removed from the access space 400, by selective etching with respect to the second sacrificial layer 14, typically by wet etching. The exposed part of the oxide layer 12 is also removed from the access space 400, to form first cavities 400a opening onto the flanks of the second layers 2 of the first stack E1. The non-exposed part of the oxide layer 12, located between the second sacrificial layer 14 and the flanks of the second stack, is preserved.

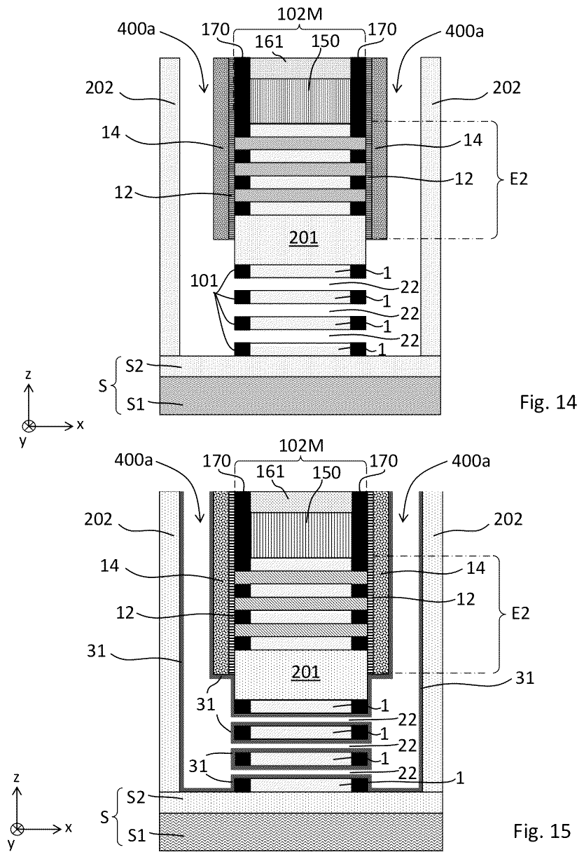

As illustrated in FIG. 14, the second layers 2 of the first stack E1 are then etched selectively at the central parts of the first layers 1 and at the internal spacers 101 of the first stack E1. The etching of the material of the second layers 2 typically has a selectivity S_{2:1} with respect to the material of the first layers 1, of at least 5:1, preferably at least 10:1. This total etching can be stopped at the time, possibly after an overetching time aiming to guarantee the total removal of the second layers 2. This total etching has an isotropic character and can be done wet or dry, from the first cavities 400a. From this etching, the second layers 2 are totally removed to form second spaces 22. The central parts of the first layers 1 are maintained by the sacrificial gates 150.

As illustrated in FIG. 15, a first gate dielectric layer 31 is then deposited in the second spaces 22 from first cavities 400a. This first gate dielectric layer 31 is typically with the basis of a material with high permittivity, for example, HfO₂-based. The first gate dielectric layer 31 is intended to form, at least partially, the gate dielectric layer between the channels of the first transistor and of the first gate-all-around. It can be formed by chemical vapour deposition (CVD), by metal organic chemical vapour deposition (MOCVD), or by atomic layer deposition (ALD). It thus covers at least the central parts of the first layers 1 and, in the first cavities 400a, the exposed faces of the second sacrificial layer 14 and of the oxide layer 12. The first gate dielectric layer 31 typically has a thickness of between 1 nm and 5 nm.

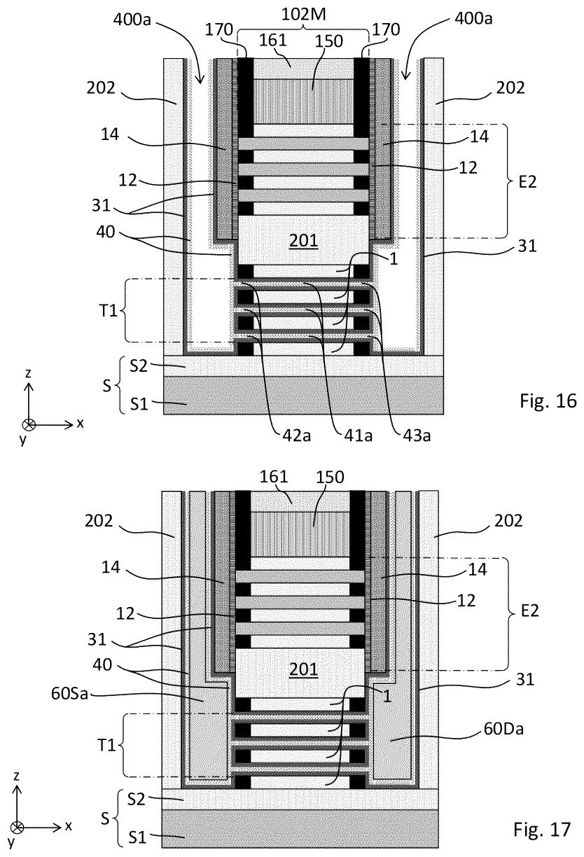

As illustrated in FIG. 16, a layer 40 with the basis of a first semiconductor material is then deposited on the first gate dielectric layer 31 in the second spaces 22. The deposition of the first semiconductor material is, in this case, configured such that the layer 40 totally fills the second spaces 22. The portions of the layer 40 located in the second spaces 22 thus have a fully controlled thickness, close to the thickness of the second initial layers. This layer 40 is intended to form the channels 41a of the first transistor T1, in vertical alignment with the sacrificial gate 150 and with the central parts of the first layers 1. This layer 40 is also intended to form the sources 42a and the drains 43a of the first transistor T1 in vertical alignment with the first internal spacers 101.

The layer 40 is also typically deposited outside of the second spaces 22, on the flanks of the internal spacers 101. This makes it possible to improve the reconnection with the sources 42a and the drains 43a of the first transistor T1. The layer 40 thus has horizontal portions in the second spaces 22, in particular between the remaining parts of the first layers 1, and vertical portions on the flanks of the first internal spacers 101. According to an option, the thickness of the vertical portions of the layer 40 is greater than the thickness of the horizontal portions of the layer 40. This makes it possible to reduce the contact resistance for the sources 42a and the drains 43a of the first transistor T1. The sources 42a and the drains 43a of the first transistor T1 can comprise horizontal portions in vertical alignment with the internal spacers 101, and at least partially, vertical portions on the flanks of the internal spacers 101.

The first semiconductor material of the layer 40 is advantageously a two-dimensional material taken from among transition metal dichalcogenides, MoS₂, for example, for a first N-type transistor, and WSe₂ or WS₂ for a first P-type transistor. Such a 2D material can be advantageously deposited in the form of a thin layer comprising 1 to 10 atomic layers, preferably 1 to 5 atomic layers. The deposition of this 2D material can be done by CVD, MOCVD or ALD. According to another option, the semiconductor material of the layer 40 is a semiconductor oxide, such as ITO (indium tin oxide), IGZO (indium gallium zinc oxide), IWO (tungsten-doped indium oxide), indium oxide In2O3.

According to a second variant not illustrated, the layer 40 with the basis of the first semiconductor material is deposited on the first gate dielectric layer 31 in the second spaces 22, without totally filling the second spaces 22. In this case, the portions of the layer 40 located in the second spaces 22 can be significantly thinner than the second initial layers. These horizontal portions can have a thickness corresponding to only a few atomic layers, for example, between 1 and 5 atomic layers of the first semiconductor material. The reduction of thickness of the layer 40 makes it possible to improve the electrostatic control of the first transistor, and therefore to reduce the dimensions of the channels 41a of the first transistor T1. The performance of the first transistor T1 can be improved. According to this second variant, a dielectric stopper is then formed between the horizontal portions of the layer 40, in order to fill the second spaces 22. This makes it possible to electrically isolate the channels 41a of the first transistor T1 from one another. This also makes it possible to improve the mechanical resistance of the device and/or to avoid deformations of the channels 41a of the first transistor T1, for example, by heating during its operation. This dielectric stopper can be formed by a CVD or ALD deposition, followed by an isotropic etching along z, conventionally.

As illustrated in FIG. 17, the first cavities 400a can then be filled by one or more metallic materials to form the first source and drain contacts 60Sa, 60Da of the first transistors T1. These metallic materials are, for example, Ti-, TIN-, W-based, or other metals making it possible to ensure a low contact resistance, such as Bi, Ni, Au, Sb, etc. A chemical-mechanical polishing CMP is typically done in order to remove excess metal deposited on the patterns 102M.

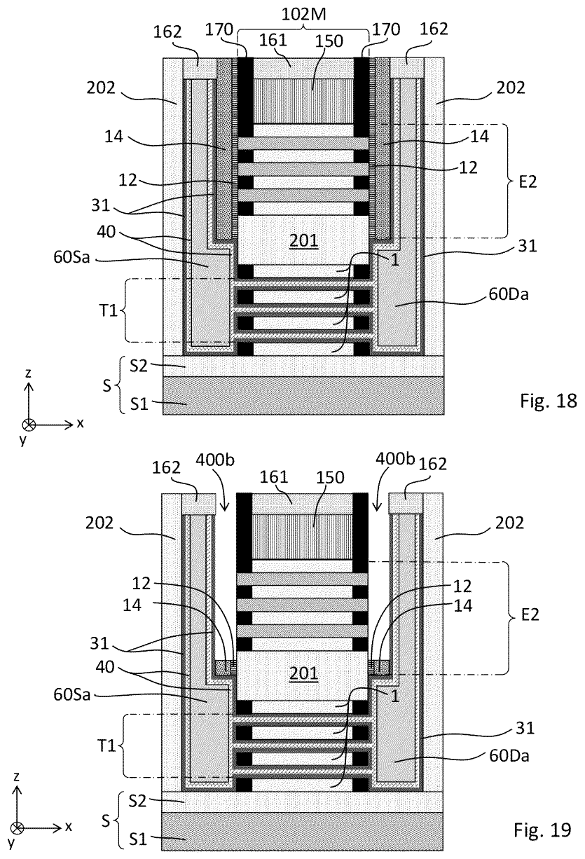

As illustrated in FIG. 18, an advantageous step consists of forming protective stoppers 162 aiming to protect the first source and drain contacts 60Sa, 60Da during subsequent steps of manufacturing the second transistor. The protective stoppers 162 can be silicon oxide SiO₂—, silicon nitride SiN-based, or an SiO2/SiN bilayer.

As illustrated in FIG. 19, the oxide layer 12 and the second sacrificial layer 14 are then removed at least partially so as to define second cavities 400b opening onto the flanks of the fourth layers 4 of the second stack E2. According to an option, a part of the oxide layer 12 and a part of the second sacrificial layer 14 are preserved at the dielectric layer 201, as illustrated in FIG. 19. According to another option not illustrated, the oxide layer 12 and the second sacrificial layer 14 are totally removed.

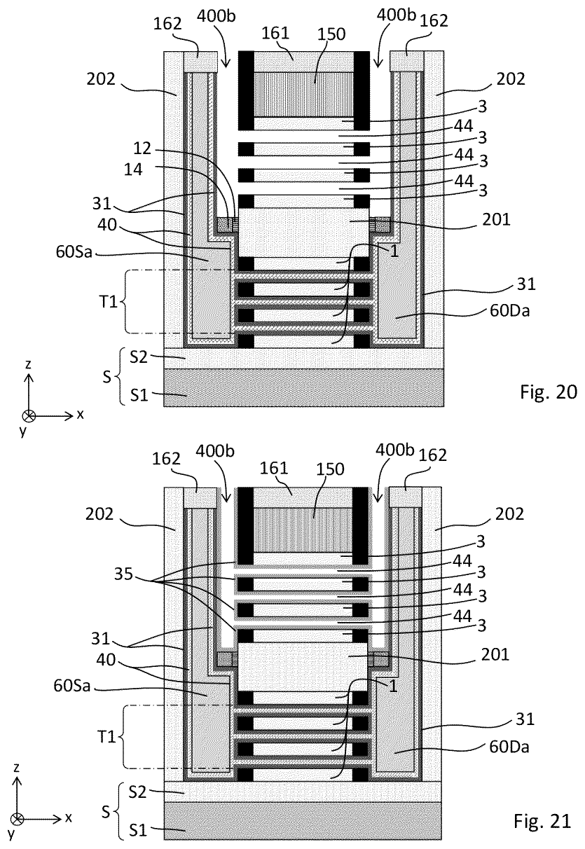

As illustrated in FIG. 20, the fourth layers 4 of the second stack E2 are than etched selectively at the central parts of the third layers 3 and at the internal spacers 131. The etching of the material of the fourth layers 4 typically has a selectivity S_{4:3} with respect to the material of the third layers 3, of at least 5:1, preferably at least 10:1. This total etching can be stopped at the time, possibly after an overetching time aiming to guarantee the total removal of the fourth layers 4. This total etching has an isotropic character and can be done wet or dry, from the second cavities 400b. From this etching, the fourth layers 4 are totally removed to form fourth spaces 44. The central parts of the third layers 3 are maintained by the sacrificial gates 150.

As illustrated in FIG. 21, a second gate dielectric layer 35 is then deposited in the fourth spaces 44 from the second cavities 400b. This second gate dielectric layer 35 is typically with the basis of a material with high permittivity, for example, HfO₂-based. The second gate dielectric layer 35 is intended to form the gate dielectric layer between the channels of the second transistor T2 and the second gate-all-around. It can be formed by CVD, MOCVD or by ALD. It thus covers at least the central parts of the third layers 3 and the exposed part of the first gate dielectric layer 31, and preferably the spacers 170 and the internal spacers 131. The second gate dielectric layer 35 typically has a thickness of between 1 nm and 5 nm. It can be with the basis of the same material forming the first gate dielectric layer 31. The first and second gate dielectric layers 31, 35 thus form a continuous isolation layer on an upper part of the first source and drain contacts 60Sa, 60Da, opposite the second cavities 400b. According to another option, the first and second gate dielectric layers 31, 35 are with the basis of two different dielectric materials. In any case, the first and second gate dielectric layers 31, 35 are in contact with one another at least at the upper part of the first source and drain contacts 60Sa, 60Da, opposite the second cavities 400b.

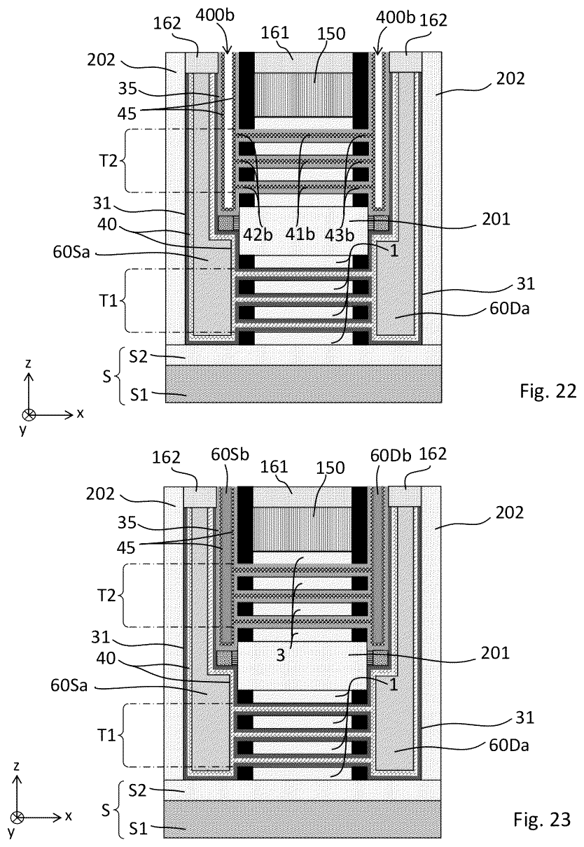

As illustrated in FIG. 22, a layer 45 with the basis of a second semiconductor material is then deposited on the second gate dielectric layer 35 in the fourth spaces 44 and in the second cavities 400b. As above, the deposition of the second semiconductor material is, in this case, configured such that the layer 45 totally fills the fourth spaces 44. The portions of the layer 45 located in the fourth spaces 44, thus have a fully controlled thickness, close to the thickness of the fourth initial layers. This layer 45 is intended to form the channels 41b of the second transistor T2 in vertical alignment with the sacrificial gate 150 and with the central parts of the third layers 3. This layer 45 is also intended to form the sources 42b and the drains 43b of the second transistor T2 in vertical alignment with the spacers 170 and with the internal spacers 131.

The layer 45 is also typically deposited outside of the fourth spaces 44, on the flanks of the spacers 170 and of the internal spacers 131. This makes it possible to improve the reconnection with the sources 42b and the drains 43b of the second transistor T2. The layer 45 thus has horizontal portions in the fourth spaces 44, in particular, between the remaining parts of the third layers 3, and vertical portions on the flanks of the spacers 170 and of the internal spacers 131. According to an option, the thickness of the vertical portions of the layer 45 is greater than the thickness of the horizontal portions of the layer 45. This makes it possible to reduce the contact resistance for the sources 42b and the drains 43b of the second transistor T2. The sources 42b and the drains 43b of the second transistor T2 can comprise the horizontal portions in vertical alignment with the spacers 170 and with the internal spacers 131, and at least partially, the vertical portions on the flanks of the spacers 170 and of the internal spacers 131.

The second semiconductor material of the layer 45 is chosen so as to form a second transistor T2 having a conductivity of the type opposite that of the first transistor T1. This second semiconductor material of the layer 45 is also preferably a two-dimensional material taken from among transition metal dichalcogenides, MoS₂, for example, for a second N-type transistor, and WSe₂ or WS₂ for a second P-type transistor. According to another option, the second semiconductor material of the layer 45 is a semiconductor oxide such as ITO (indium tin oxide), IGZO (indium gallium zinc oxide), IWO (tungsten-doped indium oxide), indium oxide In₂O₃.

The layer 45 with the basis of the second semiconductor material can also be produced according to the second variant described above.

As illustrated in FIG. 23, the second cavities 400b can then be filled with one or more metallic materials to form the second source and drain contacts 60Sb, 60 Db of the second transistor T2. These metallic materials are, for example, Ti-, TIN-, W-based, or other metals making it possible to ensure a low contact resistance such as Bi, Ni, Au, Sb, etc. A chemical-mechanical polishing CMP is typically done in order to remove excess metal deposited on the patterns 102M.

At this stage of the method, the CFET device comprises transistors T1, T2, superposed or stacked along z. The channels 41a, 41b of each transistor T1, T2 have been formed and are also stacked along z. The source 60Sa, 60Sb and drain 60Da, 60 Db contacts of each transistor T1, T2 have also been produced. The first source contact 60Sa is advantageously isolated with respect to the second source contact 60Sb by the combination of first and second gate dielectric layers 31, 35. The first drain contact 60Da is advantageously isolated with respect to the second drain contact 60 Db by the combination of first and second gate dielectric layers 31, 35.

In order to obtain superposed GAA transistors, the steps described below relate to the production of functional gates-all-around of the transistors, replacing the sacrificial gate and of the layers 1 and 3, according to two embodiments.

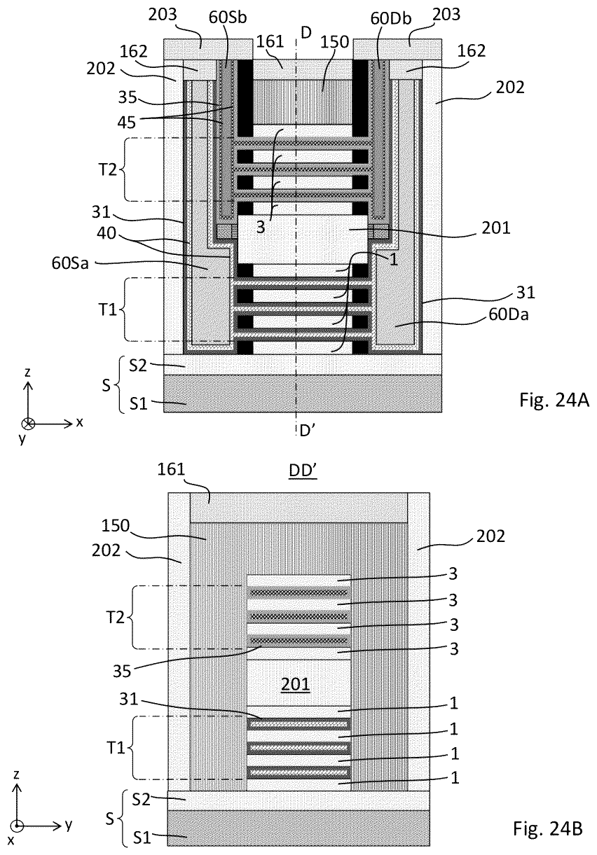

FIGS. 24A, 24B to 27A, 27B schematically illustrate, according to the first embodiment of the present invention, the production of a gate common to the transistors T1, T2 of the CFET device.

According to this first embodiment, as illustrated in FIGS. 24A, 24B, a mask 203 is formed so as to protect the first source and drain contacts 60Sa, 60Da and the second source and drain contacts 60Sb, 60 Db. This mask 203 is open so as to expose the hard mask 161 surmounting the sacrificial gate. This mask 203 can be conventionally with the basis of a dielectric material, for example, SiN- or SiO2-based.

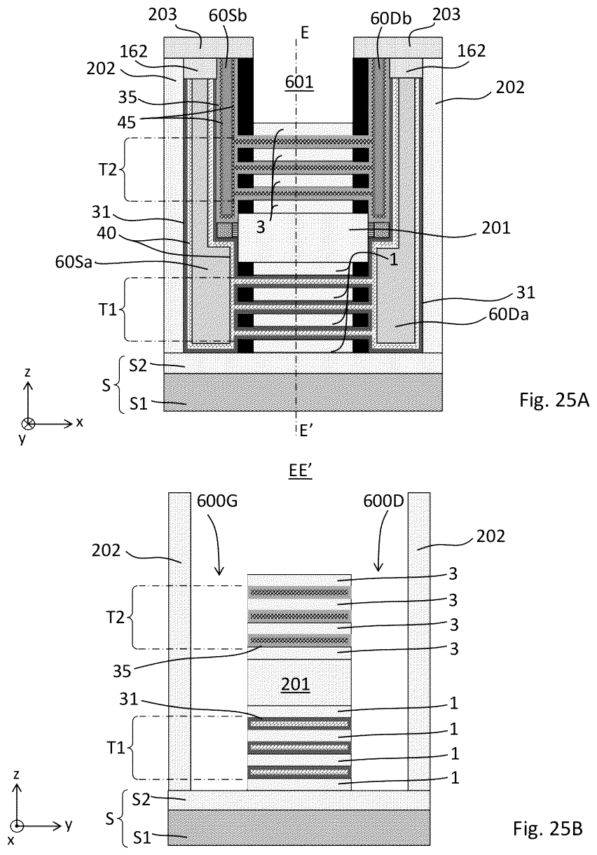

According to the first embodiment, as illustrated in FIGS. 25A, 25B, the hard mask 161 is first removed, then the sacrificial gate 150 is also removed. The latter removal can be done by wet etching stopping on the thin SiO2-based stop layer or another dielectric. This wet etching typically has a high selectivity with respect to the stop layer and/or to the spacers 170. This wet etching can be with the basis of a TMAH (tetramethylammonium hydroxide) or TEAH (tetraethylammonium hydroxide) ammoniac salt solution. This removal of the sacrificial gate 150 makes it possible to form a main space 601 and third openings 600G, 600D opening onto the central parts of the first layers 1 and the third layers 3 (FIG. 25B).

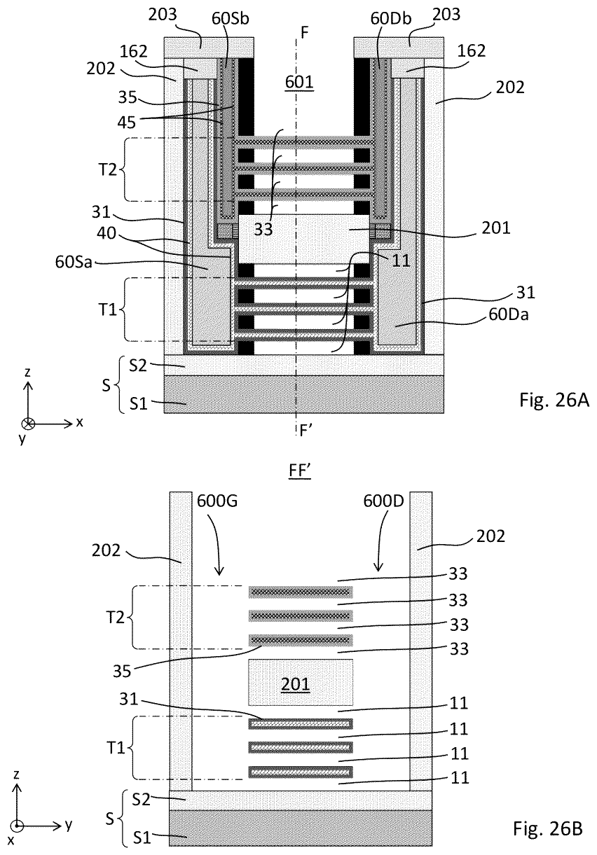

As illustrated in FIGS. 26A, 26B, the central parts of the first layers 1 and of the third layers 3 are then totally etched selectively at the internal spacers 101, 131, at the isolating layer 201, at the first gate dielectric layer 31 and at the second gate dielectric layer 35 from the third openings 600G, 600D. One or more etchings can be implemented, according to which the materials of the first layers 1 and of the third layers 3 are identical or different. To simplify, one single etching is alluded to, in this case. This etching aims to form first spaces 11 instead of the central parts of the first layers 1, and third spaces 33 instead of the central parts of the third layers 3. This total etching can be stopped at the time, possibly after an overetching time aiming to guarantee the total removal of the first material of the first material from the first layers 1 and the total removal of the third material from the third layers 3. This total etching has an isotropic character and can be done wet or dry, from the third openings 600G, 600D.

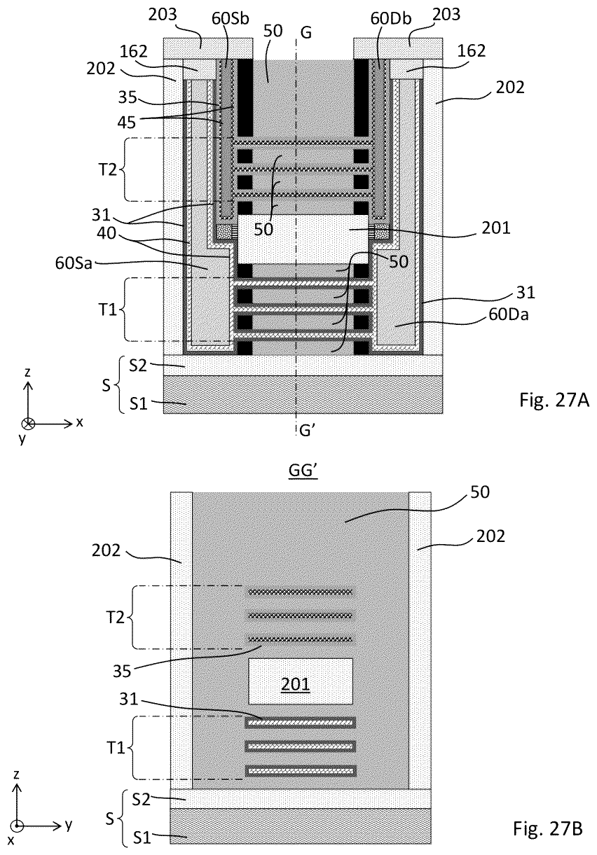

As illustrated in FIGS. 27A, 27B, the third openings 600G, 600D, the main space 601, the first spaces 11 and the third spaces 33 are then filled with one or more metallic layers, for example, TIN-, W-based, in order to form a gate 50 common to the first and second transistors T1, T2. This gate 50 is called all-around and totally surrounds the channels 41a, 41b of the first and second transistors T1, T2. According to an option, before deposition of the metallic layers of the gate 50, a dielectric layer with the basis of a material with high permittivity, for example, HfO₂-based, is deposited beforehand via the third openings 600G, 600D, in the main space 601, the first spaces 11 and the third spaces 33. This makes it possible to increase the thickness of the gate dielectric layers between the channels of the transistors T1, T2 and the gate-all-around 50. A chemical-mechanical polishing CMP is typically done in order to remove the excess metal deposited on the patterns 102M. This method, in which the functional gate 50 is produced at the end of the method, after formation of the other elements of the transistors T1, T2, in particular after formation of the channels 41a, 41b, is called “gate last”.

According to another option not illustrated, the gate 50 common to the transistors T1, T2 can be produced before the formation of the channels 41a, 41b of the transistors T1, T2, in particular before the deposition of the first sacrificial layer 13, according to a method called “gate first”.

According to the first embodiment of the present invention, a CFET device comprising superposed GAA transistors T1, T2, with a common gate 50, and having source 60Sa, 60Sb and drain 60Da, 60 Db contacts, isolated from one another by gate dielectric layers 31, 35, is produced.

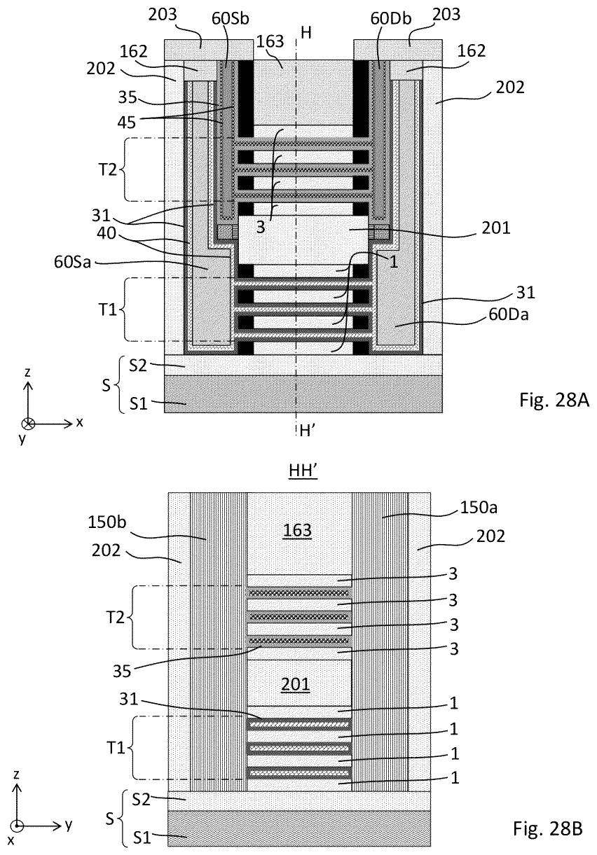

FIGS. 28A, 28B to 34A, 34B schematically illustrate a second embodiment of the method for manufacturing CFET GAA transistors having distinct gates for each transistor T1, T2. Figures nA (n=28 . . . 34) correspond to first cross-sections along a plane xz, each illustrating a different step of the manufacturing method. Figures nB (n=28 . . . 34) correspond to second cross-sections along a plane yz, each illustrating the same step as the corresponding figure nA.

According to the second embodiment, as illustrated in FIGS. 28A, 28B, the sacrificial gate is, in this case, typically separated into two distinct parts 150a, 150b. This separation can be done through a hard mask 163. In particular, before formation of the sacrificial gate 150 on the patterns 101M, the hard mask 163 is formed beforehand on the patterns 101M. After deposition of the sacrificial gate, a chemical-mechanical polishing step stopping on the hard mask 163 makes it possible to form two distinct parts 150a, 150b of the sacrificial gate. The first part 150a of the sacrificial gate extends over a first side of the pattern 101M. The second sacrificial gate part 150b extends over a second side of the pattern 101M. Below, these two distinct parts 150a, 150b are removed successively to be replaced by first and second functional gates.

The mask 203 is formed so as to protect the first source and drain contacts 60Sa, 60Da and the second source and drain contacts 60Sb, 60 Db, as above.

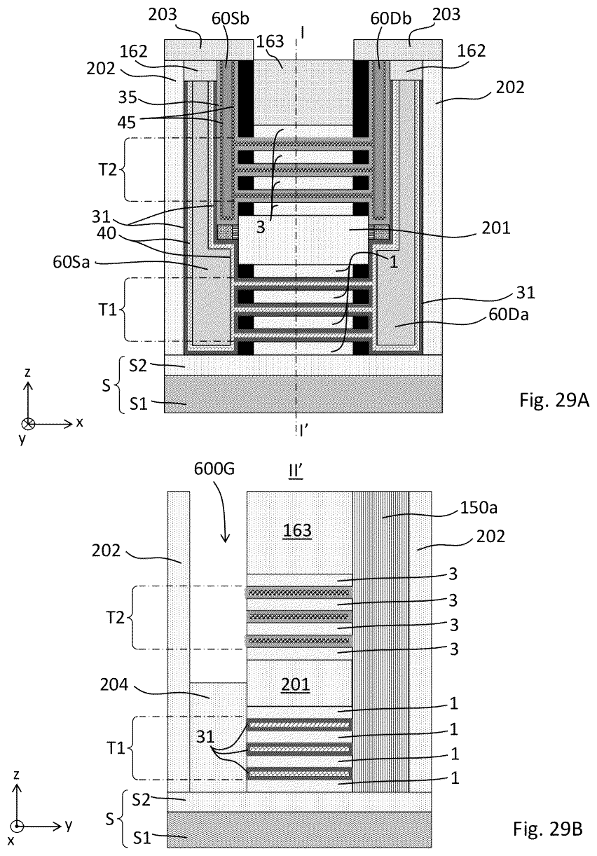

As illustrated in FIGS. 29A, 29B, the second sacrificial gate part 150b is first removed so as to form a third openings 600G exposing flanks of the third layers 3 of the second stack E2, on a second side of the pattern 101M. A second isolation portion 204, for example SiO2-based, is then formed at the bottom of the third opening 600G, at the stack E1. Only the flanks of the third layers 3 of the second stack E2 are, in this case, exposed through the opening 600G.

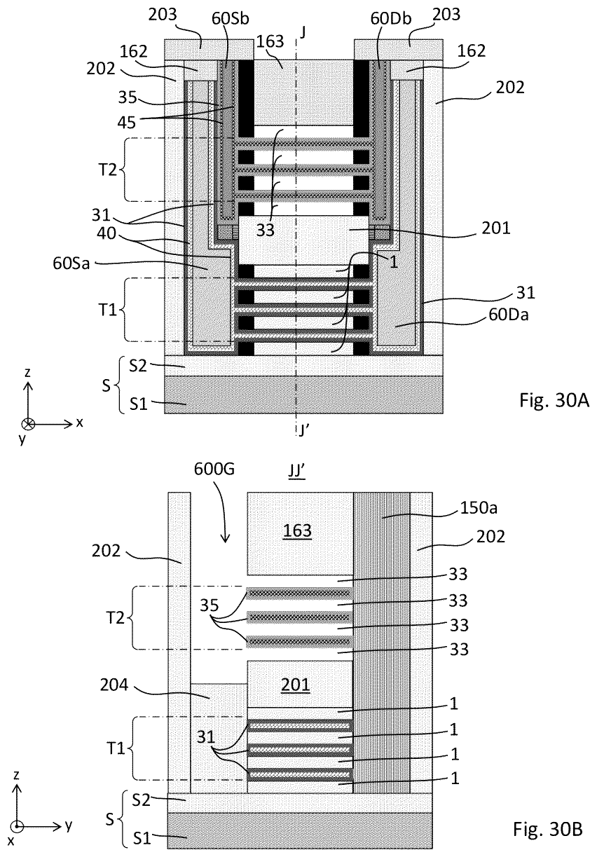

As illustrated in FIGS. 30A, 30B, the central parts of the third layers 3 are then totally etched selectively at the internal spacers 131, at the isolating layer 201, at the second gate dielectric layer 35 from the third opening 600G. This etching aims to form the third spaces 33 instead of the central parts of the third layers 3 in view of producing the second gate of the second transistor T2. This total etching can be stopped at the time, possibly after an overetching time aiming to guarantee the total removal of the third material from the third layers 3. This total etching has an isotropic character and can be done wet or dry, from the third opening 600G.

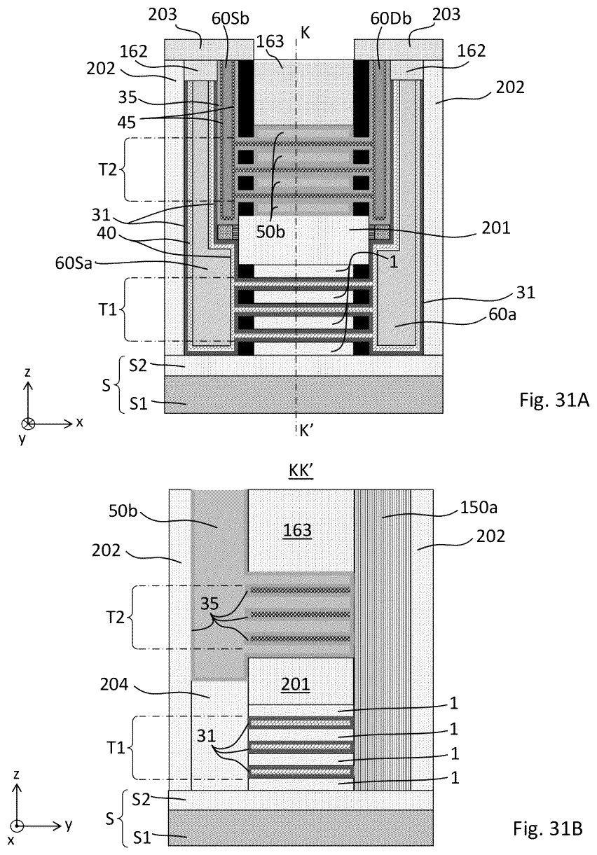

As illustrated in FIGS. 31A, 31B, the third spaces 33 and the third opening 600G are then filled to form the second gate 50b around the channels 41b of the second transistor T2. According to an option, an additional dielectric layer is deposited in the third spaces 33 on the second gate dielectric layer 35, prior to the filling of the third spaces 33 and of the third opening 600G with one or more metallic layers. As above, the metallic layers can be TIN-, W-based.

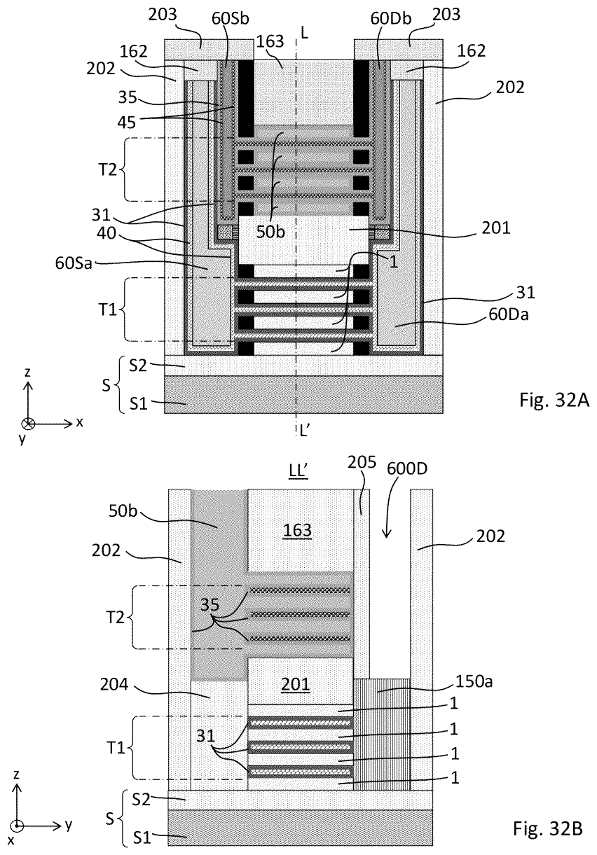

As illustrated in FIGS. 32A, 32B, the first sacrificial gate part 150a is preferably first partially removed so as to form a third opening 600D of the first side of the pattern 101M. During this intermediate step, the flanks of the second stack E2 on the first side of the pattern 101M are exposed. The flanks of the first stack E1 on the first side of the pattern 101M are masked by the remaining sacrificial gate part 150a. A first isolation portion 205, for example, SiO2-based, is then formed in the third opening 600D, on the remaining sacrificial gate part 150a, to isolate the future first gate of the first transistor with respect to the second gate 50b and to the channels 41b of the second transistor T2.

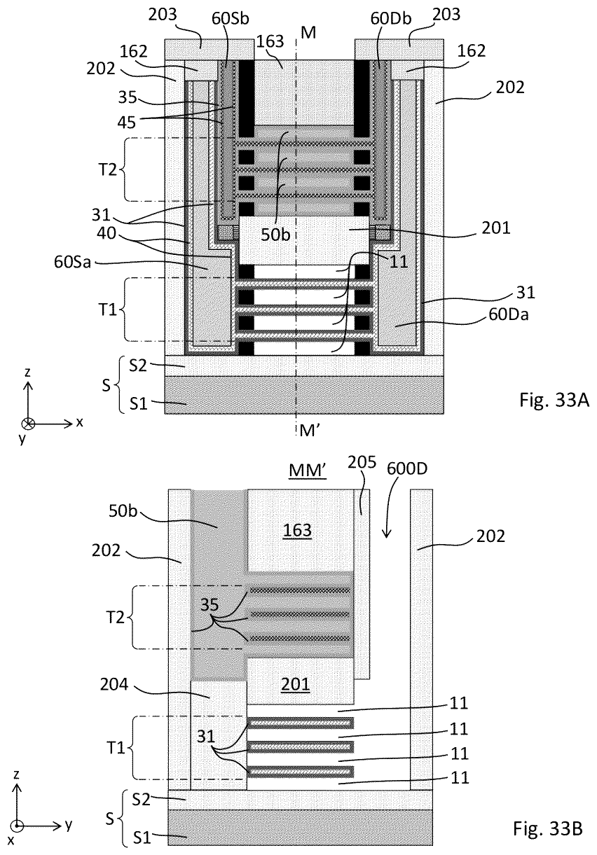

As illustrated in FIGS. 33A, 33B, the remaining sacrificial gate part 150a is then totally removed through the third opening 600D. The central parts of the first layers 1 are thus etched selectively at the internal spacers 101, at the isolating layer 201, at the first gate dielectric layer 31, from the third opening 600D. This etching aims to form first spaces 11 instead of the central parts of the first layers 1 in view of producing the first gate of the first transistor T1. This total etching can be stopped at the time, possibly after an overetching time aiming to guarantee the total removal of the first material of the first layers 1. This total etching has an isotropic character and can be done wet or dry, from the third opening 600D.

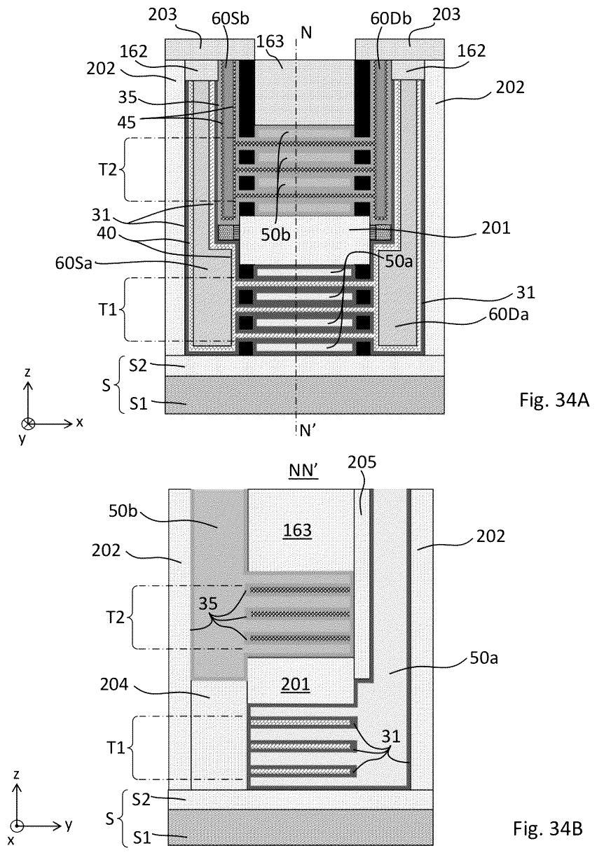

As illustrated in FIGS. 34A, 34B, the first spaces 11 and the third opening 600D are then filled to form the first gate 50a around the channels 41a of the first transistor T1. According to an option, an additional dielectric layer is deposited in the first spaces 11 on the first gate dielectric layer 31, prior to the filling of the first spaces 11 and of the third opening 600D with one or more metallic layers. As above, the metallic layers can be TIN-, W-based.

According to this second embodiment, a CFET device comprising superposed GAA transistors T1, T2, with independent gates 50a, 50b, and having source 60Sa, 60Sb and drain 60Da, 60 Db contacts, isolated from one another by the gate dielectric layers 31, 35, is done. The independent gates 50a, 50b are, in this case, electrically independent and make it possible to independently control the superposed P-type transistor and the N-type transistor.

The solutions detailed in this invention are particularly effective for manufacturing CFET devices with superposed GAA transistors. The invention is however not limited to the embodiments described above.

In particular, the embodiment described in reference to FIGS. 34A and 34B provides an isolation of the first source contact with respect to the second source contact by the first gate dielectric layer and by the second gate dielectric layer, as well as an isolation of the first drain contact with respect to the second drain contact by said first gate dielectric layer and by said second gate dielectric layer. The invention also extends to the embodiments in which the first source contact and the second drain contact are distinct and isolated from one another by the first gate dielectric layer and by the second gate dielectric layer, and in which the first drain contact and the second source contact are distinct and isolated from one another by said first gate dielectric layer and by said second gate dielectric layer.

1. A microelectronic device comprising at least two superposed transistors along a main direction, the device comprising:
a first transistor, including
at least two first channels stacked along the main direction, each channel being with a basis of a first semiconductor material,
a first source and a first drain with the basis of said first semiconductor material,
a first source contact and a first drain contact connected respectively to said first source and to said first drain,
a first so-called gate-all-around, totally surrounding at least one of the first channels, and
a first gate dielectric layer separating each first channel from the first gate-all-around, and
a second transistor, including
at least two second channels stacked along the main direction, each channel being with a basis of a second semiconductor material,
a second source and a second drain with the basis of said second semiconductor material,
a second source contact and a second drain contact connected respectively to said second source and to said second drain,
a second so called gate-all-around, totally surrounding at least one of the second channels,
a second gate dielectric layer separating each second channel of the second gate-all-around,
wherein the first source contact and one from among the second source contact and the second drain contact are distinct and isolated from one another by the first gate dielectric layer and by the second gate dielectric layer, and in that the first drain contact and the other from among the second source contact and the second drain contact are distinct and isolated from one another by said first gate dielectric layer and by said second gate dielectric layer.

2. The device according to claim 1, wherein the first gate dielectric layer and the second gate dielectric layer are with the basis of the same material, thus forming a continuous dielectric layer between the first and second source contacts and between the first and second drain contacts.

3. The device according to claim 1, wherein the first semiconductor material and the second semiconductor material are with the basis of a two-dimensional material chosen from among MX2 transition metal dichalcogenides with M taken from among molybdenum or tungsten, and X taken from among sulphur, selenium, or tellurium.

4. The device according to claim 1, wherein the first and second gates-all-around form one same gate common to the first and second transistors.

5. The device according to claim 1, wherein the first and second gates-all-around are distinct, the first gate totally surrounding each first channel of the first transistor, and the second gate totally surrounding each second channel of the second transistor.

6. The device according to claim 1, wherein the first semiconductor material has a first type of conductivity and the second semiconductor material has a second type of conductivity different from the first type of conductivity.

7. A method for manufacturing a microelectronic device according to claim 1, the method comprising:
providing, on a substrate, a first stack and a second stack superposed along the main direction, said first stack comprising a plurality of first layers made of a first material, alternated with a plurality of second layers made of a second material, said second stack comprising a plurality of third layers made of a third material, alternated with a plurality of fourth layers made of a fourth material, said first and second stacks being separated by a dielectric layer,
forming, in the superposed first stack and the second stack, first openings defining first patterns,
forming a sacrificial gate mounted on the first patterns and partially in the first openings,
forming, in the first patterns, second openings defining second patterns, on either side of the sacrificial gate,
forming a first sacrificial layer in the second openings, on flanks of the second layers of the first stack,
forming a second sacrificial layer on the first sacrificial layer and on flanks of the fourth layers of the second stack, by leaving an access space to the first sacrificial layer,
removing the first sacrificial layer, from the access space, by preserving the second sacrificial layer, so as to form first cavities opening onto the flanks of the second layers of the first stack, removing from the first cavities, the second material from the second layers selectively at the first material of the first layers, so as to form second spaces,
forming a first gate dielectric layer in the second spaces on exposed parts of the first material of the first layers, and in the first cavities on exposed parts of the second sacrificial layer,
depositing a layer with the basis of a first semiconductor material in the second spaces, on the first gate dielectric layer, so as to form:
the first channels of the first transistor with the basis of the first semiconductor material, in vertical alignment with the sacrificial gate, and
a first source and a first drain of the first transistor with the basis of the first semiconductor material, on either side of the first channels of the first transistor,
filling the first cavities with a first electrically conductive material to form first source and drain contacts of the first transistor,
removing the second sacrificial layer, so as to form second cavities opening onto the flanks of the fourth layers of the second stack,
removing, from the second cavities, the fourth material from the fourth layers selectively at the third material from the third layers, so as to form fourth spaces,
forming a second gate dielectric layer in the fourth spaces on exposed parts of the third material of the third layers, and in the second cavities on the first gate dielectric layer,
depositing a layer with the basis of a second semiconductor material in the fourth spaces, on the second gate dielectric layer, so as to form:
second channels of the second transistor with the basis of the second semiconductor material, in vertical alignment with the sacrificial gate, and
a second source and a second drain of the second transistor with the basis of the second semiconductor material, on either side of the second channels of the second transistor,
filling the second cavities with a second electrically conductive material to form second source and drain contacts of the second transistor,
removing the sacrificial gate so as to form third openings,
removing, from the third openings, the first layers and the third layers, to form first spaces and third spaces respectively, and
filling the first and third spaces, to respectively form the first and second gates-all-around of the first and second transistors.

8. The manufacturing method according to claim 7, further comprising:
forming first spacers between the first gate-all-around and the first source and drain contacts, and
forming second spacers between the second gate-all-around and the second source and drain contacts.

9. The manufacturing method according to claim 8, wherein the formation of the first and second spacers comprises:
forming spacers bordering the sacrificial gate and bearing on the first patterns,
before the formation of the first sacrificial layer, partially removing, from the second openings, the first material from the first layers selectively at the second material of the second layers, so as to form first spacer cavities, in vertical alignment with the spacers,
filling the first spacer cavities with a first dielectric material to form the first spacers,
before the formation of the second sacrificial layer, partially removing, from the second openings, the third material from the third layers selectively at the fourth material of the fourth layers, so as to form second spacer cavities, preferably in vertical alignment with the spacers, and
filling the second spacer cavities with a second dielectric material to form the second spacers.

10. The manufacturing method according to claim 2, wherein the first material of the first layers is identical to the third material of the third layers, and wherein the first and second spacers are simultaneously formed.

11. The manufacturing method according to claim 7, wherein the sacrificial gate comprises a distinct first part and a second part, and wherein the removal of the sacrificial gate comprises:
a first removal of the first sacrificial gate part configured to form a third opening only opening onto flanks of the first layers, of a first side only of the first pattern, followed by a removal of the first layers from said third opening to form the first spaces, and a filling of said first spaces to form the first gate-all-around of the first transistor, and
a second removal of the second sacrificial gate part configured to form a third opening only opening onto flanks of the third layers, of a second side only of the first pattern, followed by a removal of the third layers from said third opening to form the third spaces, and a filling of said third spaces to form the second gate-all-around of the second transistor.

12. The manufacturing method according to claim 11, wherein the first removal comprises a formation of a first isolation portion on flanks of the first stack at the first side of the first pattern, before filling of the first spaces to form the first gate-all-around.

13. The manufacturing method according to claim 11, wherein the second removal comprises a formation of a second isolation portion on flanks of the first stack at the second side of the first pattern, before filling of the third spaces to form the second gate-all-around.

14. The manufacturing method according to claim 11, wherein the second gate-all-around is formed before the first gate-all-around.

15. The manufacturing method according to claim 11, further comprising, before the removal of the sacrificial gate, a separation of the sacrificial gate into a distinct first part and a second part, said first and second sacrificial gate parts extending respectively over the first and second sides of the first pattern, the first removal being done on the first gate part and the second removal being done on the second gate part.

16. The manufacturing method according to claim 15, wherein, before formation of the sacrificial gate, a hard mask is formed on the first patterns, and wherein the separation of the sacrificial gate is done by chemical-mechanical polishing stopping on said hard mask.
